(19) United States
(12) Patent Application Publication
(10) Pub. No.: US 2001/0016022 A1
(43) Pub. Date: Aug. 23, 2001

(54) Delay time adjusting circuit comprising frequency dividers having different frequency division rates

(75) Inventors: Nobutaka Taniguchi, Kawasaki (JP); Hiroyoshi Tomita, Kawasaki (JP)

Correspondence Address: ARENT FOX KINTNER PLOTKIN & KAHN, 1050 CONNECTICUT AVENUE, N.W., SUITE 600, WASHINGTON, DC, 20036, US

(73) Assignee: FUJITSU LIMITED

(21) Appl. No.: 09/772,080

(22) Filed: Jan. 30, 2001

(30) Foreign Application Priority Data
Feb. 23, 2000 (JP) 2000-046226

(51) Int. Cl. H04L 7/00; H04L 25/00; H04L 25/40; H03D 3/24

(52) U.S. Cl. 375/371; 375/375

(57) ABSTRACT

A delay time adjusting circuit adjusts a delay time of an input signal so that a phase of the input signal and a phase of an output signal match each other. The circuit comprises first dividing means for dividing a frequency of the input signal by a first frequency division rate; delaying means for delaying the input signal by a predetermined time; second dividing means for dividing a frequency of the input signal delayed by the delaying means by a second frequency division rate; comparing means for comparing a phase of a signal generated by the first dividing means and a phase of a signal generated by the second dividing means; and adjusting means for adjusting the predetermined time according to a comparison result obtained by the comparing means.

### BACKGROUND OF THE INVENTION

1. Field of the Invention

The present invention generally relates to a delay time adjusting circuit and, more particularly, to a delay time adjusting circuit and a delay time adjusting method which circuit and method adjust a delay time of a signal transmitted in a semiconductor integrated circuit.

2. Description of the Related Art

Conventionally, a semiconductor integrated circuit, such as a DDR (Double Data Rate)-SDRAM, which is required to operate at high speed and has a DLL (Delay Locked Loop) circuit mounted thereon, comprises a delay time adjusting circuit to adjust a phase of a clock signal.

FIG. 1 is a circuit diagram of the conventional delay time adjusting circuit. As shown in FIG. 1, the conventional delay time adjusting circuit comprises an input buffer 1, an output buffer 5, frequency dividers 2 and 4, a DLL array 3, a dummy circuit 6, a phase comparator 8 and a delay adjuster 10.

In the conventional delay time adjusting circuit, a clock signal is input into the input buffer 1, which outputs a signal Cin. The frequency divider 2 and the DLL array 3 are connected to the input buffer 1. The frequency divider 4 and the output buffer 5 are connected to an output terminal of the DLL array 3. The frequency divider 2 outputs a target clock signal tclk. The DLL array 3 outputs a signal Cout. The output buffer 5 outputs a clock signal delayed by the DLL array 3. The frequency division rates of the frequency dividers 2 and 4 are equal.

The dummy circuit 6 is connected to the frequency divider 4 and outputs a delay clock signal dclk. The phase comparator 8 is connected to the frequency divider 2 and an output terminal of the dummy circuit 6, and feeds back a result signal ‘out’ to the delay adjuster 10, according to the supplied target clock signal tclk and the fed-back delay clock signal dclk. An output terminal of the delay adjuster 10 is connected to the DLL array 3. The delay adjuster 10 supplies a control signal CS to the DLL array 3.

FIG. 2 is a circuit diagram of the DLL array 3 shown in FIG. 1 As shown in FIG. 2, the DLL array 3 comprises a switching unit 31 including a plurality of parallel-connected switches SW1 to SWn, and inverters INV1 to INVn respectively arranged to correspond to the switches SW1 to SWn. Switching of the switches SW1 to SWn included in the switching unit 31 is controlled by the controlling signal CS supplied by the delay adjuster 10. The signal Cin is delayed by a time td in each of the inverters INV1 to INVn.

In the above-mentioned delay time adjusting circuit, supposing that a delay time at the input buffer 1 is d1 and a delay time at the output buffer 5 is d2, a delay time at the dummy circuit 6 is (d1+d2). Also, supposing that a delay time of the DLL array 3 is d3, the clock signal input into the input buffer 1 and output from the output buffer 5 is delayed by a time (d1+d2+d3).

Also, supposing that delay times at the frequency dividers 2 and 4 are d4, the clock signal input into the input buffer 1 and then input into the phase comparator 8 as the target clock signal tclk is delayed by a time (d1+d4). In this case, the clock signal input into the input buffer 1 and consequently input into the phase comparator 8 as the delay clock signal dclk is delayed by a time (d1+d3+d4+(d1+d2)).

Accordingly, a difference in the delay times between the target clock signal tclk and the delay clock signal dclk is (d1+d2+d3). This difference equals the delay time (d1+d2+d3) of the clock signal input into the input buffer 1 and output from the output buffer 5. Thereby, in order to match phases of the clock signal input into the input buffer 1 and the clock signal output from the output buffer 5, the delay adjuster 10 adjusts the delay time d3 of the DLL array 3 so that the difference (d1+d2+d3) in the delay times between the target clock signal tclk and the delay clock signal dclk equals a time corresponding to a number n (1, 2 or other natural numbers) of clocks of the clock signal.

Here, a description will be given, with reference to FIG. 3 to FIG. 7, of operations of the above-mentioned delay time adjusting circuit. In a case, shown in FIG. 3, where a phase of a delay clock signal dclk indicated by FIG. 3-(b) is a time F1 behind a phase of the target clock signal tclk indicated by FIG. 3-(a), at so-called rise times T1, T2 and T3 when the target clock signal tclk rises from a low level (L) to a high level (H), the delay clock signal dclk is at a low level (L). In this case, the phase comparator 8 supplies the delay adjuster 10 with a result signal ‘out’ indicating a judgment (decrease) that the phase of the delay clock signal dclk is behind the phase of the target clock signal tclk.

Thereby, the delay adjuster 10 supplies the DLL array 3 with a control signal CS according to the result signal ‘out’ so as to shorten a delay time in the DLL array 3 by the time F1. These operations match the phase of the delay clock signal dclk to the phase of the target clock signal tclk. Likewise, the same or analogous operations apply to each of cases shown in FIG. 4 to FIG. 6, where a phase of a delay clock signal dclk is a time F2, F3 or F4 (each longer than the time F1) behind a phase of the target clock signal tclk.

In a case, shown in FIG. 7, where a phase of a delay clock signal dclk indicated by FIG. 7-(b) is a still longer time behind a phase of a target clock signal tclk indicated by FIG. 7-(a), at the times T2 and T3, the delay clock signal dclk is at a high level (H). In this case, the phase comparator 8 supplies the delay adjuster 10 with a result signal ‘out’ indicating a judgment (increase) that a first clock of the delay clock signal dclk is ahead of a second clock of the target clock signal tclk.

Thereby, the delay adjuster 10 supplies the DLL array 3 with a control signal CS according to the result signal ‘out’ so as to lengthen a delay time in the DLL array 3 by a time F5. In such a case shown in FIG. 7, the phase of the delay clock signal dclk is matched to the phase of the target clock signal tclk, based on the second clock of the target clock signal tclk.

FIG. 8 is a circuit diagram of the phase comparator 8 shown in FIG. 1. As shown in FIG. 8, the phase comparator 8 comprises NAND circuits 80 to 85. The target clock signal tclk is supplied to the NAND circuits 81 and 82. The delay clock signal dclk is supplied to the NAND circuit 83. The result signal ‘out’ is output from an output terminal of the NAND circuit 84.

FIG. 9 is a waveform diagram indicating an operation of the above-mentioned phase comparator 8 in a case where a first clock of a delay clock signal dclk is behind a first clock of a target clock signal tclk. FIG. 9-(a) indicates the target clock signal tclk. FIG. 9-(b) indicates the delay clock signal dclk. FIG. 9-(c) indicates fluctuations of electric potential at an output node NA of the NAND circuit 81. FIG. 9-(d) indicates fluctuations of electric potential at an output node NB of the NAND circuit 82. FIG. 9-(e) indicates fluctuations of electric potential at an output node NC of the NAND circuit 80. FIG. 9-(f) indicates fluctuations of electric potential at an output node ND of the NAND circuit 83. FIG. 9-(g) indicates the result signal ‘out’.

In the case shown in FIG. 9, where the first clock of the delay clock signal dclk is behind the first clock of the target clock signal tclk, before a rise time TA of the target clock signal tclk, the NAND circuits 84 and 85 latch the result signal ‘out’ at a high level or a low level. Then, at the rise time TA when the target clock signal tclk rises to a high level, the electric potential at the output node NB falls to a low level, and consequently, the result signal ‘out’ is fixed at the low level. Thereby, the phase comparator 8 supplies the delay adjuster 10 with the result signal ‘out’ at the low level. That is, the phase comparator 8 supplies the delay adjuster 10 with the result signal ‘out’ indicating a judgment (decrease) that the first clock of the delay clock signal dclk is behind the first clock of the target clock signal tclk.

FIG. 10 is a waveform diagram indicating an operation of the above-mentioned phase comparator 8 in a case where a first clock of a delay clock signal dclk is ahead of a first clock of a target clock signal tclk. FIG. 10-(a) indicates the target clock signal tclk. FIG. 10-(b) indicates the delay clock signal dclk. FIG. 10-(c) indicates fluctuations of electric potential at the output node NA of the NAND circuit 81. FIG. 10-(d) indicates fluctuations of electric potential at the output node NB of the NAND circuit 82. FIG. 10-(e) indicates fluctuations of electric potential at the output node NC of the NAND circuit 80. FIG. 10-(f) indicates fluctuations of electric potential at the output node ND of the NAND circuit 83. FIG. 10-(g) indicates the result signal ‘out’.

In the case shown in FIG. 10, where the first clock of the delay clock signal dclk is ahead of the first clock of the target clock signal tclk, before the rise time TA of the target clock signal tclk, the NAND circuits 84 and 85 latch the result signal ‘out’ at a high level or a low level. Then, at the rise time TA when the target clock signal tclk rises to a high level, the electric potential at the output node NA falls to a low level, and consequently, the result signal ‘out’ is fixed at the high level. Thereby, the phase comparator 8 supplies the delay adjuster 10 with the result signal ‘out’ at the high level. That is, the phase comparator 8 supplies the delay adjuster 10 with the result signal ‘out’ indicating a judgment (increase) that the first clock of the delay clock signal dclk is ahead of the first clock of the target clock signal tclk.

It should be noted that the above-mentioned delay time of the DLL array 3 comprises a variable component delay time that can be adjusted by switching the switches SW1 to SWn included in the switching unit 31, and a fixed component delay time that is intrinsic to circuit properties of the DLL array 3.

The conventional delay time adjusting circuit operates as mentioned above. However, as a semiconductor integrated circuit is increasingly made to operate at high speed, and accordingly, a high-frequency signal is supplied to the input buffer 1, the above-mentioned fixed component delay time occupies a larger portion of a required total delay time in a locking-on where the phases of the delay clock signal and the target clock signal are matched within a tolerance range.

As a countermeasure to this situation, conventionally, the frequency division rates of the frequency dividers 2 and 4 are raised so as to postpone in time a target used in matching the phases.

However, since dividing a frequency of the clock signal by n in the frequency divider 2 means that the target is postponed by a time corresponding to 2ⁿ clocks, when n is increased so as to raise the above-mentioned frequency division rates, an enormous number of the delay stages have to be provided in the DLL array 3 in consideration of a low-frequency band of the clock signal. This increases a scale of the delay time adjusting circuit.

### SUMMARY OF THE INVENTION

It is a general object of the present invention to provide an improved and useful delay time adjusting method and a delay time adjusting circuit in which method and circuit the above-mentioned problems are eliminated.

A more specific object of the present invention is to provide a delay time adjusting method which can adjust a delay time of a signal at high speed and a delay time adjusting circuit which is reduced in scale but can realize the above-mentioned method.

In order to achieve the above-mentioned objects, there is provided according to one aspect of the present invention a delay time adjusting circuit which adjusts a delay time of an input signal so that a phase of the input signal and a phase of an output signal match each other, the circuit comprising:

first dividing means for dividing a frequency of the input signal by a first frequency division rate;

delaying means for delaying the input signal by a predetermined time;

second dividing means for dividing a frequency of the input signal delayed by the delaying means by a second frequency division rate;

comparing means for comparing a phase of a signal generated by the first dividing means and a phase of a signal generated by the second dividing means; and

adjusting means for adjusting the predetermined time according to a comparison result obtained by the comparing means.

According to the present invention, the first dividing means for dividing a frequency of the input signal can change the first frequency division rate so that a target in adjusting the delay time can be set at arbitrary intervals. Thus, decreasing the first frequency division rate can shorten a time required to adjust the delay time, and can reduce a circuit scale of the delaying means for delaying the input signal. Also, the second dividing means for dividing a frequency of the delayed input signal can change the second frequency division rate so as to arbitrarily determine how frequently the phases are compared. Thus, increasing the second frequency division rate so as to compare the phases less frequently can reduce an amount of electric power to be consumed.

Additionally, in the present invention, the first frequency division rate may be reduced to 1 so as to make unnecessary a circuit element that realizes the first dividing means for dividing a frequency, reducing a circuit scale. Additionally, the comparing means for comparing phases may supply a signal indicating the comparison result to the adjusting means according to the signal generated by the second dividing means for dividing a frequency. According to the present invention, changing the second frequency division rate in the second dividing means for dividing a frequency can adjust how frequently the phases are compared.

In order to achieve the above-mentioned objects, there is provided according to another aspect of the present invention a delay time adjusting method which adjusts a delay time of an input signal so that a phase of the input signal and a phase of an output signal match each other, the method comprising:

a first step of comparing a phase of a signal generated by dividing, by a first frequency division rate, a frequency of the input signal, and a phase of a signal generated by dividing, by a second frequency division rate, a frequency of the input signal delayed by a predetermined time; and

a second step of adjusting the predetermined time according to a comparison result obtained by the first step of comparing so that the phase of the signal generated by dividing by the first frequency division rate and the phase of the signal generated by dividing by the second frequency division rate match each other.

According to the present invention, the first frequency division rate can be changed so that a target in adjusting the delay time can be set at arbitrary intervals. Thus, decreasing the first frequency division rate can shorten a time required to adjust the delay time. Also, the second frequency division rate can be changed so as to arbitrarily determine how frequently the phases are compared. Thus, increasing the second frequency division rate so as to compare the phases less frequently can reduce an amount of electric power to be consumed.

Additionally, in the present invention, the first frequency division rate may be reduced to 1 so as to use the input signal as a target in comparing the phases. This way, the first step of comparing phases can obtain the comparison result more quickly, enhancing a circuit operation speed. Additionally, in the second step, the above-mentioned predetermined time may be adjusted at a frequency according to the signal generated by dividing a frequency of the delayed input signal by the second frequency division rate. According to the present invention, changing the second frequency division rate can adjust how frequently the phases are compared.

Other objects, features and advantages of the present invention will become more apparent from the following detailed description when read in conjunction with the accompanying drawings.

### BRIEF DESCRIPTION OF THE DRAWINGS

FIG. 1 is a circuit diagram of a conventional delay time adjusting circuit;

FIG. 2 is a circuit diagram of a DLL (Delay Locked Loop) array shown in FIG. 1;

FIG. 3 is a first waveform diagram indicating an operation of the conventional delay time adjusting circuit shown in FIG. 1;

FIG. 4 is a second waveform diagram indicating an operation of the conventional delay time adjusting circuit shown in FIG. 1;

FIG. 5 is a third waveform diagram indicating an operation of the conventional delay time adjusting circuit shown in FIG. 1;

FIG. 6 is a fourth waveform diagram indicating an operation of the conventional delay time adjusting circuit shown in FIG. 1;

FIG. 7 is a fifth waveform diagram indicating an operation of the conventional delay time adjusting circuit shown in FIG. 1;

FIG. 8 is a circuit diagram of a phase comparator shown in FIG. 1;

FIG. 9 is a waveform diagram indicating an operation of the phase comparator shown in FIG. 8 in a case where a first clock of a delay clock signal is behind a first clock of a target clock signal;

FIG. 10 is a waveform diagram indicating an operation of the phase comparator shown in FIG. 8 in a case where a first clock of a delay clock signal is ahead of a first clock of a target clock signal;

FIG. 11 is a circuit diagram of a delay time adjusting circuit according to an embodiment of the present invention;

FIG. 12 is a circuit diagram of a delay time adjusting circuit according to another embodiment of the present invention;

FIG. 13 is a first waveform diagram indicating an operation of the delay time adjusting circuit shown in FIG. 12;

FIG. 14 is a second waveform diagram indicating an operation of the delay time adjusting circuit shown in FIG. 12;

FIG. 15 is a third waveform diagram indicating an operation of the delay time adjusting circuit shown in FIG. 12;

FIG. 16 is a fourth waveform diagram indicating an operation of the delay time adjusting circuit shown in FIG. 12;

FIG. 17 is a fifth waveform diagram indicating an operation of the delay time adjusting circuit shown in FIG. 12;

FIG. 18 is a circuit diagram of a phase comparator shown in FIG. 12;

FIG. 19 is a waveform diagram indicating an operation of the phase comparator shown in FIG. 18 in a case where a first clock of a delay clock signal is behind a first clock of a target clock signal; and

FIG. 20 is a waveform diagram indicating an operation of the phase comparator shown in FIG. 18 in a case where a first clock of a delay clock signal is ahead of a first clock of a target clock signal.

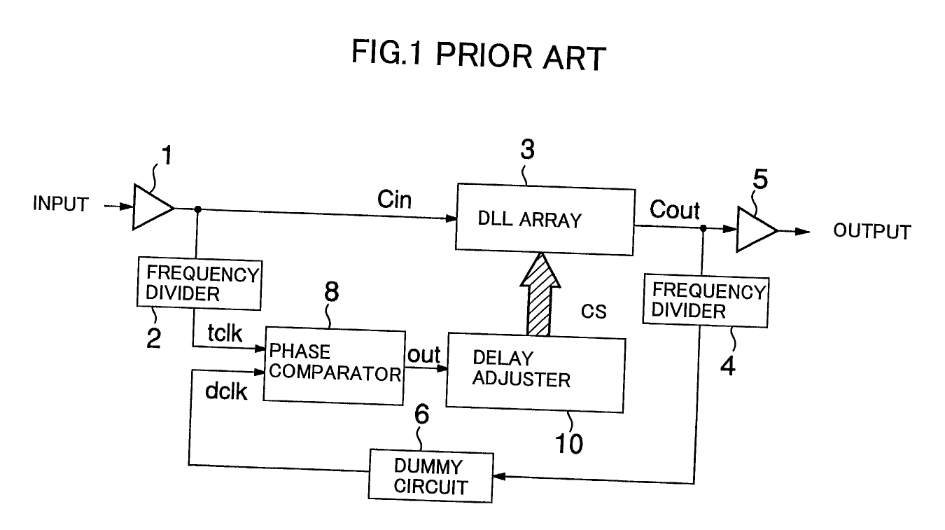

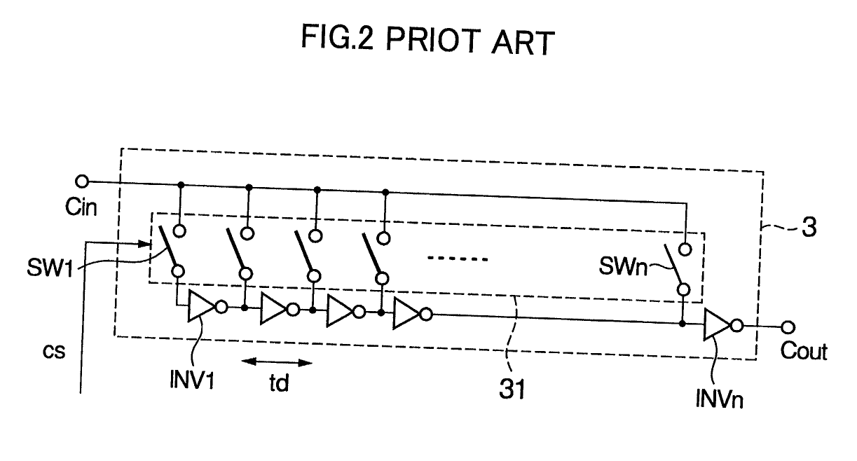

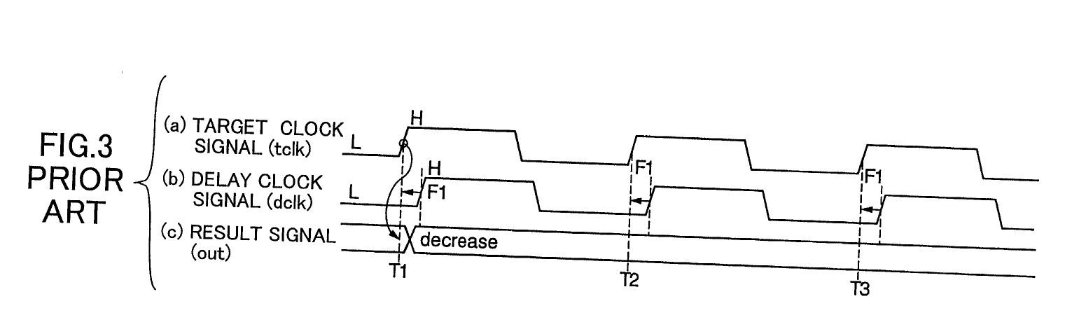

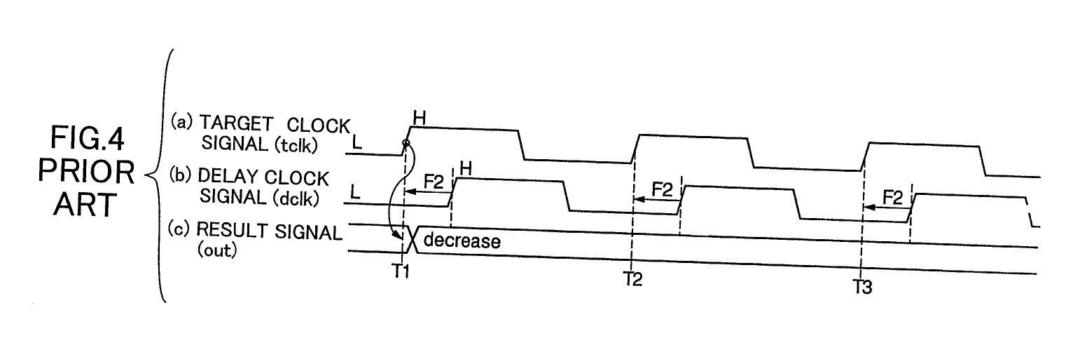

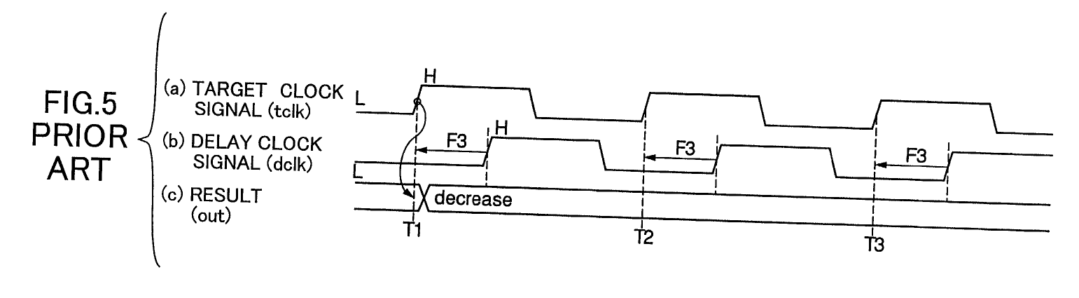

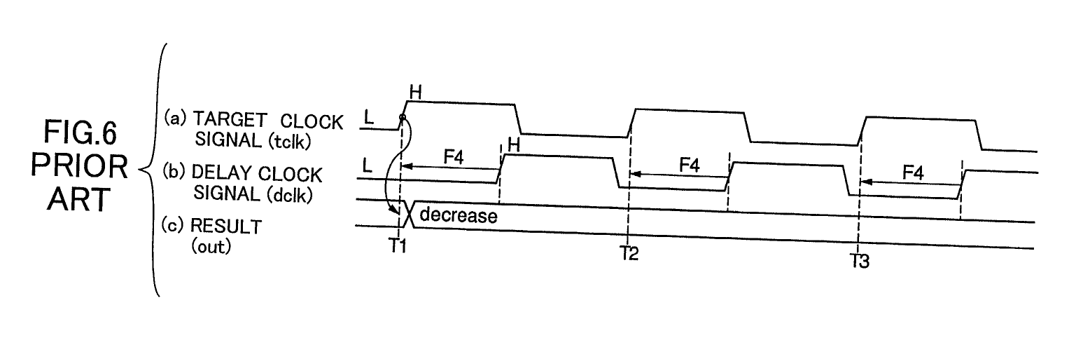

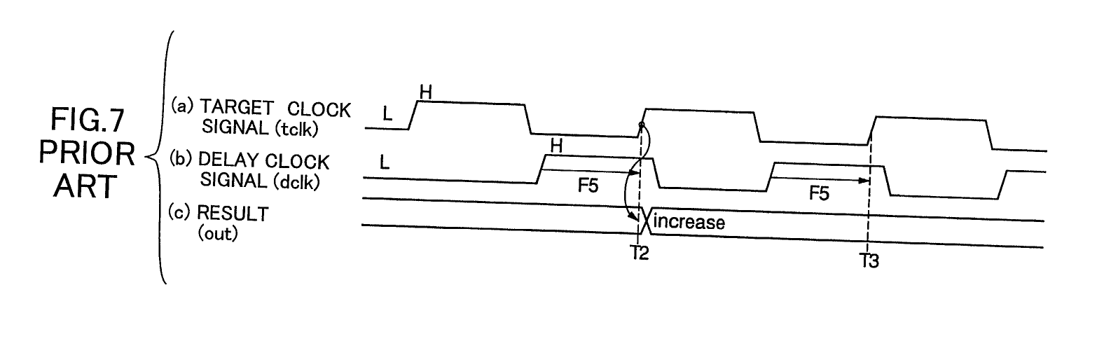

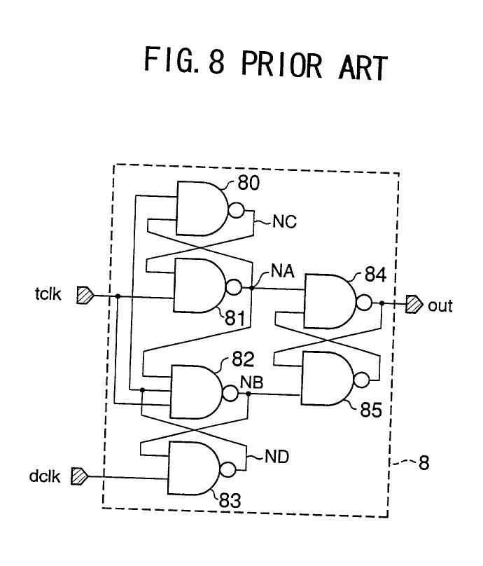

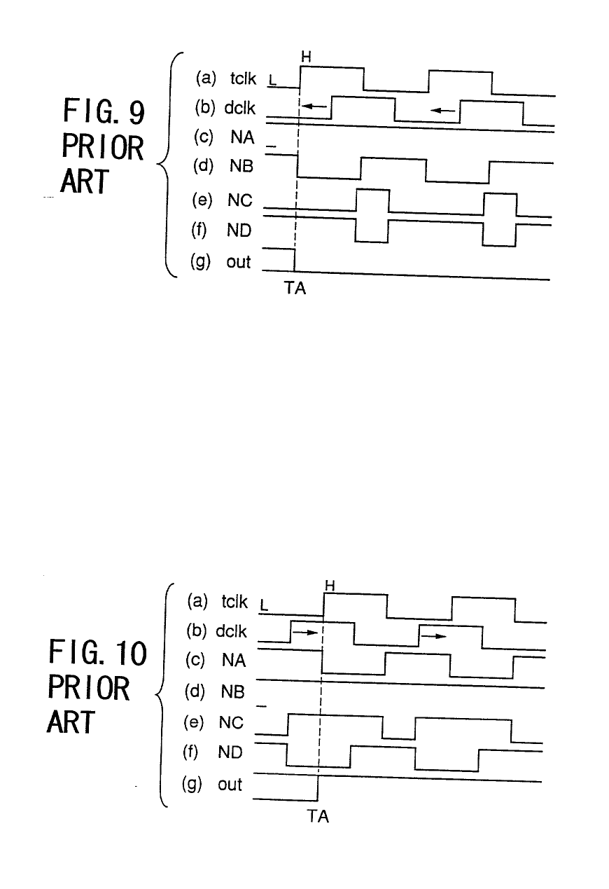

### DETAILED DESCRIPTION OF THE PREFERRED EMBODIMENTS

A description will now be given, with reference to the drawings, of embodiments according to the present invention. Elements in the drawings that are identical or equivalent are referenced by the same characters.

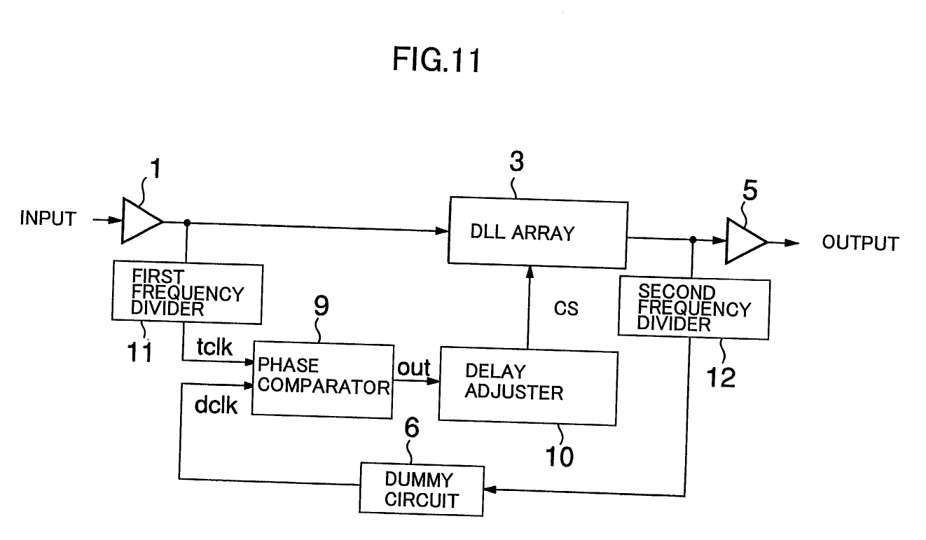

FIG. 11 is a circuit diagram of a delay time adjusting circuit according to an embodiment of the present invention. As shown in FIG. 11, the delay time adjusting circuit according to the present embodiment comprises the input buffer 1, the output buffer 5, a first frequency divider 11, a second frequency divider 12, the DLL array 3, the dummy circuit 6, a phase comparator 9 and the delay adjuster 10.

As described in detail hereinafter, the first frequency divider 11 may be considered to be an element that determines a target used in adjusting a phase of a signal. The second frequency divider 12 may be considered to be an element that determines how frequently the phase of a signal has a chance to be adjusted. Therefore, when a frequency division rate of the second frequency divider 12 is increased so that the phase of a signal has a less frequent chance to be adjusted, only a smaller amount of electric current is consumed.

In the above-mentioned delay time adjusting circuit, a clock signal is input into the input buffer 1. The first frequency divider 11 and the DLL array 3 are connected to the input buffer 1. The second frequency divider 12 and the output buffer 5 are connected to the output terminal of the DLL array 3. The first frequency divider 11 outputs the target clock signal tclk. The above-mentioned delay time adjusting circuit is characterized in that frequency division rates are different between the first frequency divider 11 and the second frequency divider 12.

The dummy circuit 6 is connected to the second frequency divider 12 and outputs the delay clock signal dclk. The phase comparator 9 is connected to the first frequency divider 11 and the output terminal of the dummy circuit 6, and outputs the result signal ‘out’. The delay adjuster 10 is connected to the phase comparator 9, and the output terminal of the delay adjuster 10 is connected to the DLL array 3. The delay adjuster 10 supplies the control signal CS to the DLL array 3.

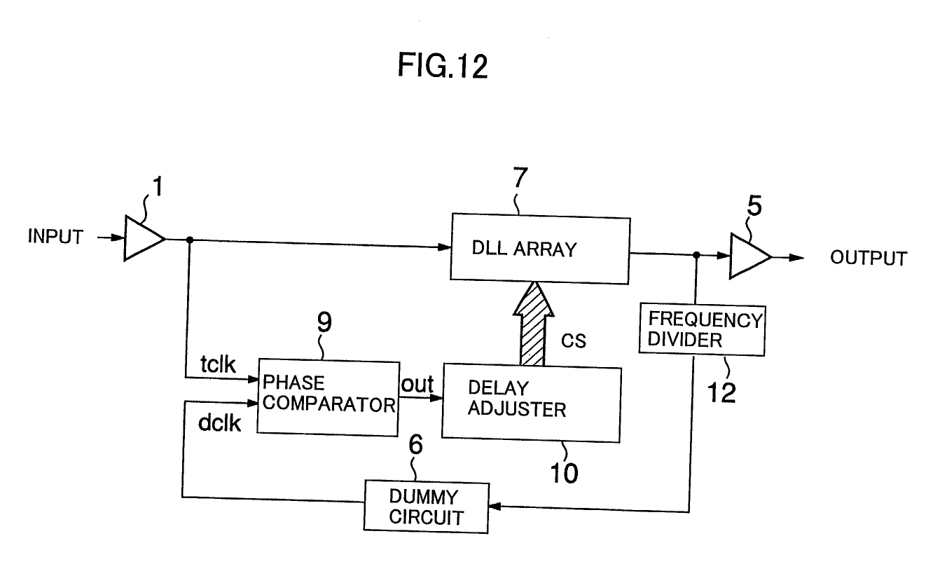

The frequency division rate of the first frequency divider 11 may be set to 1. In this case, the first frequency divider 11 supplies an input signal to the phase comparator 9 as it is. Hence, the delay time adjusting circuit has a structure equivalent to a delay time adjusting circuit shown in FIG. 12 without the first frequency divider 11, wherein an output signal from the input buffer 1 is supplied directly to the phase comparator 9 as the target clock signal tclk. The delay time adjusting circuit shown in FIG. 12 requires a smaller number of delay stages (the inverters INV1 to INVn) to be included in a DLL array 7 than that of a conventional technology, as mentioned hereinafter.

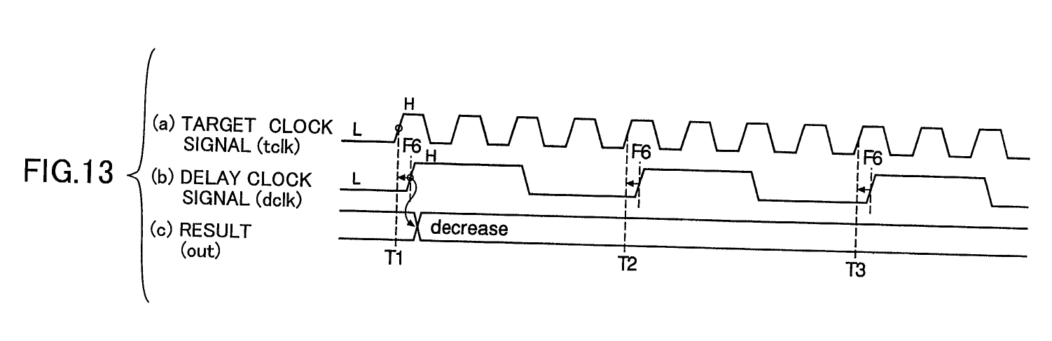

Next, a description will be given, with reference to FIG. 13 to FIG. 17, of operations of the above-mentioned delay time adjusting circuit shown in FIG. 12. Here, a frequency division rate of the second frequency divider 12 shown in FIG. 12 is set to four.

Accordingly, a delay clock signal dclk indicated by FIG. 13-(b) has one fourth the frequency of that of a target clock signal tclk indicated by FIG. 13-(a). In a case where a first clock of the delay clock signal dclk is a time F6 behind a first clock of the target clock signal tclk, at the rise times T1, T2 and T3 when the target clock signal tclk rises from a low level (L) to a high level (H), the delay clock signal dclk is at a low level (L). In this case, the phase comparator 9 supplies the delay adjuster 10 with a result signal ‘out’ indicating a judgment (decrease) that a phase of the delay clock signal dclk is behind a phase of the target clock signal tclk.

Thereby, the delay adjuster 10 supplies the DLL array 7 with a control signal CS according to the result signal ‘out’ so as to shorten a delay time in the DLL array 7 by the time F6. These operations match the phase of the delay clock signal dclk to the phase of the target clock signal tclk.

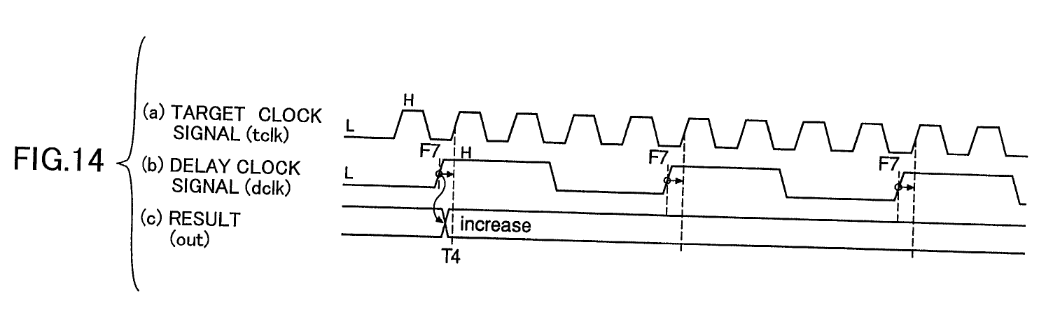

In a case, shown in FIG. 14, where a first clock of a delay clock signal dclk indicated by FIG. 14-(b) is a longer time behind a first clock of a target clock signal tclk indicated by FIG. 14-(a), at a time T4, the delay clock signal dclk is at a high level (H). In this case, the phase comparator 9 supplies the delay adjuster 10 with a result signal ‘out’ indicating a judgment (increase) that the first clock of the delay clock signal dclk is ahead of a second clock of the target clock signal tclk. Thereby, the delay adjuster 10 supplies the DLL array 7 with a control signal CS according to the result signal ‘out’ so as to lengthen a delay time in the DLL array 7 by a time F7. In such a case shown in FIG. 14, the phase of the delay clock signal dclk is matched to the phase of the target clock signal tclk, based on the second clock of the target clock signal tclk.

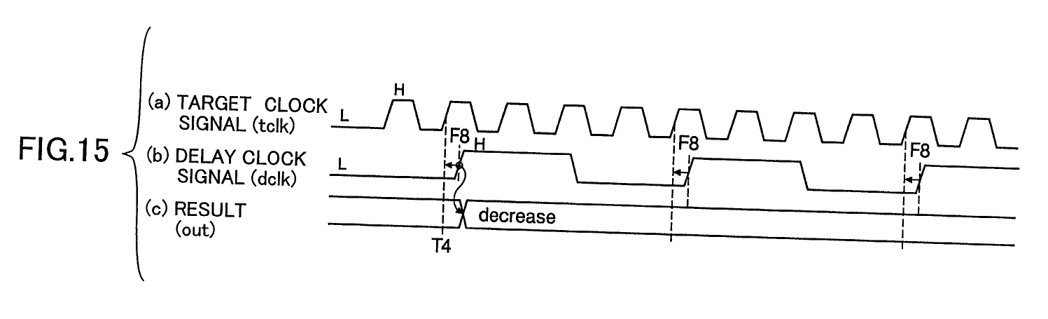

In a case, shown in FIG. 15, where a first clock of a delay clock signal dclk indicated by FIG. 15-(b) is an even longer time behind a first clock of a target clock signal tclk indicated by FIG. 15-(a), at the time T4 when the target clock signal tclk rises from a low level (L) to a high level (H), the delay clock signal dclk is at a low level (L). Accordingly, in this case, the phase comparator 9 supplies the delay adjuster 10 with a result signal ‘out’ indicating a judgment (decrease) that the first clock of the delay clock signal dclk is behind a second clock of the target clock signal tclk.

Thereby, the delay adjuster 10 supplies the DLL array 7 with a control signal CS according to the result signal ‘out’ so as to shorten a delay time in the DLL array 7 by a time F8. These operations match the phase of the delay clock signal dclk to the phase of the target clock signal tclk.

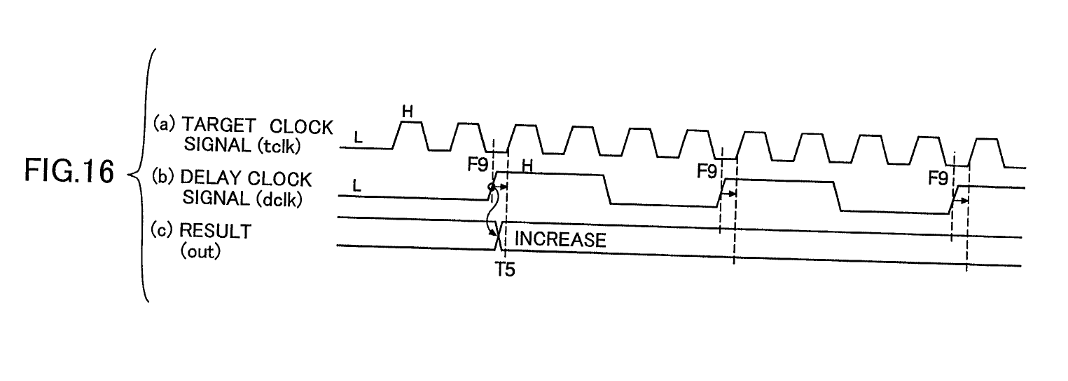

In a case, shown in FIG. 16, where a phase of a delay clock signal dclk indicated by FIG. 16-(b) is a still longer time behind a phase of a target clock signal tclk indicated by FIG. 16-(a), at a time T5, the delay clock signal dclk is at a high level (H). In this case, the phase comparator 9 supplies the delay adjuster 10 with a result signal ‘out’ indicating a judgment (increase) that a first clock of the delay clock signal dclk is ahead of a third clock of the target clock signal tclk.

Thereby, the delay adjuster 10 supplies the DLL array 7 with a control signal CS according to the result signal ‘out’ so as to lengthen a delay time in the DLL array 7 by a time F9. In such a case shown in FIG. 16, the phase of the delay clock signal dclk is matched to the phase of the target clock signal tclk, based on the third clock of the target clock signal tclk.

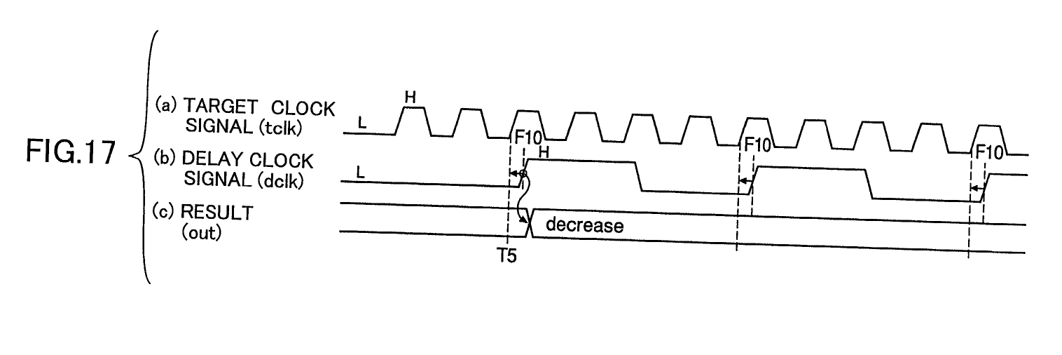

In a case, shown in FIG. 17, where a phase of a delay clock signal dclk indicated by FIG. 17-(b) is a yet longer time behind a phase of a target clock signal tclk indicated by FIG. 17-(a), at the time T5 when the target clock signal tclk rises from a low level (L) to a high level (H), the delay clock signal dclk is at a low level (L). Accordingly, in this case, the phase comparator 9 supplies the delay adjuster 10 with a result signal ‘out’ indicating a judgment (decrease) that a first clock of the delay clock signal dclk is behind a third clock of the target clock signal tclk.

Thereby, the delay adjuster 10 supplies the DLL array 7 with a control signal CS according to the result signal ‘out’ so as to shorten a delay time in the DLL array 7 by a time F10. These operations match the phase of the delay clock signal dclk to the phase of the target clock signal tclk.

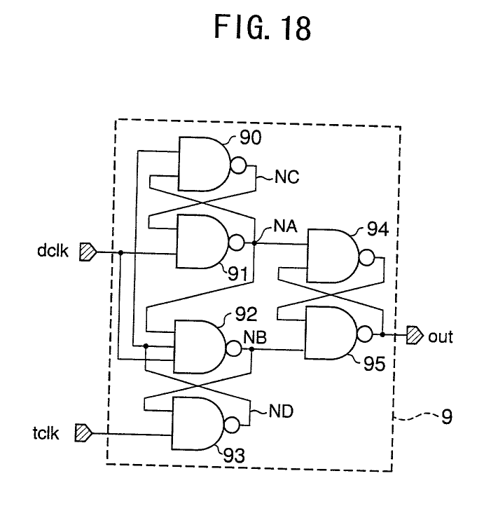

FIG. 18 is a circuit diagram of the phase comparator 9 shown in FIG. 12. As shown in FIG. 18, the phase comparator 9 comprises NAND circuits 90 to 95. The delay clock signal dclk is supplied to the NAND circuits 91 and 92. The target clock signal tclk is supplied to the NAND circuit 93. The result signal ‘out’ is output from an output terminal of the NAND circuit 95. As described in detail hereinafter, the phase comparator 9 outputs the result signal ‘out’ indicating a judgment made according to a rise time of the delay clock signal dclk. Accordingly, when a frequency division rate of the second frequency divider 12 is increased so that a phase of a signal has a less frequent chance to be adjusted, only a smaller amount of electric current is consumed.

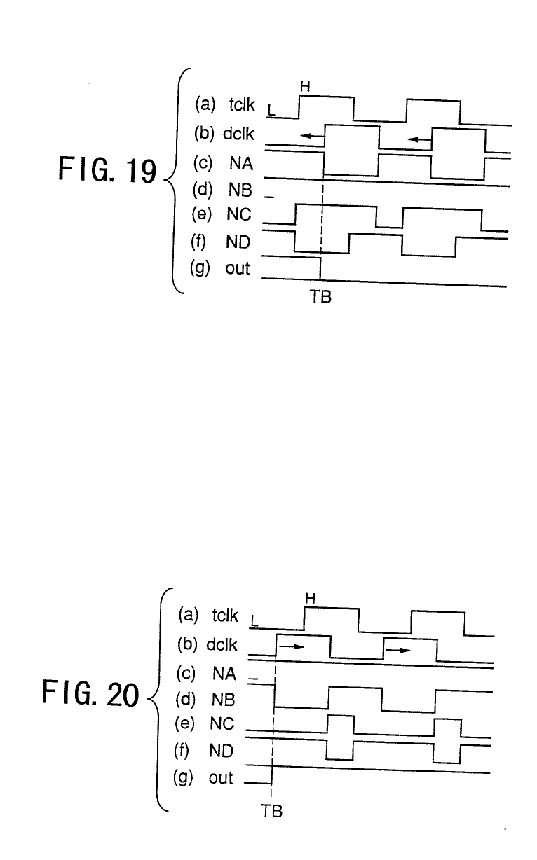

FIG. 19 is a waveform diagram indicating an operation of the above-mentioned phase comparator 9 in a case where a first clock of a delay clock signal dclk is behind a first clock of a target clock signal tclk. FIG. 19-(a) indicates the target clock signal tclk. FIG. 19-(b) indicates the delay clock signal dclk. FIG. 19-(c) indicates fluctuations of electric potential at an output node NA of the NAND circuit 91. FIG. 19-(d) indicates fluctuations of electric potential at an output node NB of the NAND circuit 92. FIG. 19-(e) indicates fluctuations of electric potential at an output node NC of the NAND circuit 90. FIG. 19-(f) indicates fluctuations of electric potential at an output node ND of the NAND circuit 93. FIG. 19-(g) indicates the result signal ‘out’.

In the case shown in FIG. 19, where the first clock of the delay clock signal dclk is behind the first clock of the target clock signal tclk, before a rise time TB of the delay clock signal dclk, the NAND circuits 94 and 95 latch the result signal ‘out’ at a high level or a low level. Then, when the delay clock signal dclk rises to a high level at the rise time TB, the electric potential at the output node NA falls to a low level, and consequently, the result signal ‘out’ is fixed at the low level. Thereby, the phase comparator 9 supplies the delay adjuster 10 with the result signal ‘out’ at the low level. That is, the phase comparator 9 supplies the delay adjuster 10 with the result signal ‘out’ indicating a judgment (decrease) that the first clock of the delay clock signal dclk is behind the first clock of the target clock signal tclk.

FIG. 20 is a waveform diagram indicating an operation of the above-mentioned phase comparator 9 in a case where a first clock of a delay clock signal dclk is ahead of a first clock of a target clock signal tclk. FIG. 20-(a) indicates the target clock signal tclk. FIG. 20-(b) indicates the delay clock signal dclk. FIG. 20-(c) indicates fluctuations of electric potential at the output node NA of the NAND circuit 91. FIG. 20-(d) indicates fluctuations of electric potential at the output node NB of the NAND circuit 92. FIG. 20-(e) indicates fluctuations of electric potential at the output node NC of the NAND circuit 90. FIG. 20-(f) indicates fluctuations of electric potential at the output node ND of the NAND circuit 93. FIG. 20-(g) indicates the result signal ‘out’.

In the case shown in FIG. 20, where the first clock of the delay clock signal dclk is ahead of the first clock of the target clock signal tclk, before the rise time TB of the delay clock signal dclk, the NAND circuits 94 and 95 latch the result signal ‘out’ at a high level or a low level. Then, when the delay clock signal dclk rises to a high level at the rise time TB, the electric potential at the output node NB falls to a low level, and consequently, the result signal ‘out’ is fixed at the high level. Thereby, the phase comparator 9 supplies the delay adjuster 10 with the result signal ‘out’ at the high level. That is, the phase comparator 9 supplies the delay adjuster 10 with the result signal ‘out’ indicating a judgment (increase) that the first clock of the delay clock signal dclk is ahead of the first clock of the target clock signal tclk.

In the above-mentioned cases, a frequency division rate of the target clock signal tclk to an input clock signal supplied to the input buffer 1 is 1. Therefore, the target clock signal tclk has a higher frequency than that in a conventional delay time adjusting circuit. Accordingly, clocks that the phase comparator 9 can use as a target in comparing the phases of the clock signals appear more frequently in a unit period of time. Thereby, since the nearest clock, whether behind or ahead, of the target clock signal tclk to the first clock of the delay clock signal dclk is used as a target in matching the phases of the clock signals as mentioned above, a time by which to match the phases of the clock signals can be made smaller than in a conventional delay time adjusting circuit.

Hence, the delay time adjusting circuit according to the present embodiment can shorten a length of a delay-time adjustment so as to quickly perform the adjustment of the delay time. Additionally, in a low-frequency band of the input clock signal supplied to the input buffer 1, the DLL array 7 having a smaller number of the delay stages (the inverters INV1 to INVn) than that of a conventional technology is sufficient to adjust the delay time. This reduces a scale of the delay time adjusting circuit.

The present invention is not limited to the specifically disclosed embodiments, and variations and modifications may be made without departing from the scope of the present invention.

The present application is based on Japanese priority application No. 2000-046226 filed on Feb. 23, 2000, the entire contents of which are hereby incorporated by reference.

What is claimed is:

1. A delay time adjusting circuit which adjusts a delay time of an input signal so that a phase of said input signal and a phase of an output signal match each other, the circuit comprising:
first dividing means for dividing a frequency of said input signal by a first frequency division rate;
delaying means for delaying said input signal by a predetermined time;
second dividing means for dividing a frequency of said input signal delayed by said delaying means by a second frequency division rate;
comparing means for comparing a phase of a signal generated by said first dividing means and a phase of a signal generated by said second dividing means; and
adjusting means for adjusting said predetermined time according to a comparison result obtained by said comparing means.

2. The delay time adjusting circuit as claimed in claim 1, wherein said first frequency division rate is 1.

3. The delay time adjusting circuit as claimed in claim 1, wherein said comparing means supplies a signal indicating said comparison result to said adjusting means according to said signal generated by said second dividing means.

4. A delay time adjusting method which adjusts a delay time of an input signal so that a phase of said input signal and a phase of an output signal match each other, the method comprising:
a first step of comparing a phase of a signal generated by dividing, by a first frequency division rate, a frequency of said input signal, and a phase of a signal generated by dividing, by a second frequency division rate, a frequency of said input signal delayed by a predetermined time; and
a second step of adjusting said predetermined time according to a comparison result obtained by said first step of comparing so that said phase of said signal generated by dividing by said first frequency division rate and said phase of said signal generated by dividing by said second frequency division rate match each other.

5. The delay time adjusting method as claimed in claim 4, wherein said first frequency division rate is 1.

6. The delay time adjusting method as claimed in claim 4, wherein said second step includes adjusting said predetermined time at a frequency according to said signal generated by dividing by said second frequency division rate.
